(19) United States
(12) Patent Application Publication
(10) Pub. No.: US 2026/0140202 A1
(43) Pub. Date: May 21, 2026

(54) ELECTRICAL WIRING DEVICE WITH SELF-TEST AND MISWIRE DETECTION

(71) Applicant: Pass & Seymour, Inc., Syracuse, NY (US)

(72) Inventors: Joshua P. Haines, Marcellus, NY (US); Frederick Duffy, Middletown, PA (US)

(73) Assignee: Pass & Seymour, Inc., Syracuse, NY (US)

(21) Appl. No.: 19/395,672

(22) Filed: Nov. 20, 2025

Related U.S. Application Data
(60) Provisional application No. 63/722,958, filed on Nov. 20, 2024.

(51) Int. Cl. G01R 31/52; G01R 31/55

(52) U.S. Cl. CPC G01R 31/52; G01R 31/55

(57) ABSTRACT

The present disclosure relates to electrical wiring devices, specifically ground fault circuit interrupters (GFCIs) with integrated self-test and miswire detection capabilities. The device comprises line and load hot terminals, line and load neutral terminals, a differential transformer with a sense coil, a circuit interrupter, and a controller. The controller is configured to periodically initiate a simulated fault self-test, allowing the fault condition to persist in a non-trip test state and triggering the circuit interrupter only if a fault is not detected within a predetermined period. The controller also detects miswire conditions by monitoring power at the line hot terminal during trip events and maintains a miswire state in memory if improper wiring is detected.

### CROSS REFERENCE TO RELATED APPLICATIONS

The present application claims priority to and the benefit of U.S. Provisional Patent Application No. 63/722,958, filed on November 20, 2024, the entirety of which is incorporated herein by reference.

### FIELD OF INVENTION

The present disclosure relates generally to electrical wiring devices, and particularly to ground fault circuit interrupters (GFCIs) with integrated self-test and miswire detection capabilities.

### BACKGROUND

As those of ordinary skill in the art understand, electrical distribution systems incorporate a variety of wiring devices throughout residential, commercial, and industrial structures. These devices include outlet receptacles, switches, protective wiring devices, and combinations thereof. Ground fault circuit interrupter (GFCI) devices are widely deployed in areas requiring enhanced protection against electric shock, such as in bathrooms, kitchens or any location near to a sink, bathtub, or shower. Each such device employs interrupting contacts to disconnect the load from the supply when a ground fault is detected, thereby mitigating the risk of electrocution and fire.

Most of these devices comprise line and load terminals, a differential sensing coil for detecting current imbalances, and a circuit for detecting a fault and triggering the interrupting contacts. The devices further include a manual test button and perform periodic self-tests to verify proper operation. Upon fault detection, the trip unit actuates a solenoid, relay, or solid-state release to open the line contacts.

Previous self-testing relied on creating a simulated fault for a limited duration before the full trip threshold is reached, i.e., a duration designed to prevent tripping of the interrupting contacts. This approach was necessary to avoid nuisance trips that would occur if the simulated were permitted to persist long enough to trip the device. A drawback to this approach resides in partial fault simulations that terminate before the full trip threshold is reached, thereby preserving continuity during testing but leaving marginal components of the fault detection path untested. As a result, what is needed is a self-test approach that exercises the full fault detection path under actual operating conditions without inducing nuisance trips.

Another significant issue that has not been adequately addressed concerns the detection of miswired line and neutral connections. Miswire refers to a condition wherein the device installer connects the AC supply voltage to the feed-through load terminals (which are intended to be connected to downstream receptacles) instead of the line terminals of the device. If the miswired condition is not detected, the load terminals provided by the receptacles on the face of the electrical wiring device can be unprotected in the presence of a fault condition. Previous solutions for detecting miswire typically relied on additional circuits solely designed for detecting the miswire, increasing the cost and complexity of the electrical wiring device.

### SUMMARY

In one embodiment, the present disclosure pertains to an electrical wiring device for use within a residential or commercial electrical power system. The device includes a line hot terminal and a load hot terminal interconnected by a hot conductor, and a line neutral terminal and a load neutral terminal interconnected by a neutral conductor. A sense coil is provided, being configured to generate a signal proportional to the vector difference of currents in the hot and neutral conductors. A circuit interrupter having separable contacts is disposed between the line hot and load hot terminals. A controller is configured to initiate a simulated fault self-test. During the self-test, the controller enters a non-trip test state in which detection of a fault based on the sense coil output does not actuate the interrupt assembly, and the controller is further configured to trigger the interrupt assembly if no fault is detected within a predetermined period. Upon detecting the fault, the controller can exit the non-trip test state. In some embodiments, the self-test is initiated by activating a solid-state switch disposed in a conductor loop routed through the transformer coils. An indicator is provided to signal a failed self-test.

In another embodiment, the present disclosure is directed to an electrical wiring device that includes the same line and load hot terminals, line and load neutral terminals, sense coil, and circuit interrupter as described above. The controller is configured to detect a trip event of the interrupt assembly and, before losing power, determine whether the line hot terminal remains connected to mains. If the line hot terminal is not connected to the mains, the controller maintains a miswire state. Determining whether the line hot terminal is connected to mains can be accomplished by detecting zero-crossings at an input representing the hot-terminal voltage. A capacitor may be provided to supply power to the controller after the interrupt assembly trips. Furthermore, an auxiliary switch can provide a conditioned signal for trip detection. Upon subsequent power-up, the controller is configured to disable further operation by actuating the interrupt assembly when a miswire state indicator is stored.

Additional features and advantages of the disclosed subject matter will be set forth in the detailed description which follows, and in part will be readily apparent to those skilled in the art from that description or recognized by practicing the disclosed subject matter as described herein, including the detailed description, the claims, and the accompanying drawings.

### BRIEF DESCRIPTION OF DRAWINGS

FIG. 1 is a circuit schematic illustrating a ground fault circuit interrupter device with integrated self-test and miswire detection functionalities in accordance with an example of the present disclosure.

FIG. 2 is a flowchart illustrating a method for performing a simulated fault self-test in a GFCI device in accordance with an example of the present disclosure.

FIG. 3 is a flowchart illustrating a method for detecting a miswire state in a GFCI device in accordance with an example of the present disclosure.

### DETAILED DESCRIPTION

The following detailed description provides various embodiments of the disclosed subject matter and is intended to facilitate understanding of the presented concepts. It is to be understood that the embodiments described herein are illustrative and not restrictive, as numerous variations, modifications, and alternative arrangements may be made without departing from the scope of the disclosed subject matter. The disclosed subject matter generally pertains to electrical wiring devices, particularly ground fault circuit interrupters (GFCIs) with integrated self-test and miswire detection capabilities, and may be applied across residential, commercial, and industrial settings.

For clarity and brevity, certain well-known components, configurations, and methods commonly understood by those skilled in the art may be omitted or described in less detail. The disclosed subject matter encompasses various implementations, including rearrangements of components, alternative circuit designs, and modifications to algorithms, provided they align with the principles and objectives disclosed herein.

The present system addresses the above-described limitations by integrating advanced self-test and miswire detection capabilities into a single electrical wiring device. The disclosed solution employs a specialized algorithm within a controller to perform periodic self-tests that exercise the full fault detection path under actual operating conditions. Unlike prior designs, the self-test mechanism allows simulated fault conditions to persist for a duration that would normally trigger a trip, while the controller is configured to suppress the trip during the test window. This is permitted, in part, because the controller that is responsible for initiating the self-test is also responsible for initiating the trip of the interrupting contacts, enabling verification of the device’s fault detection capabilities without inducing nuisance trips. If the expected fault is not detected within the predetermined test period, the device triggers the circuit interrupter or otherwise provides an indication of test failure, promoting reliable fault detection and adherence to safety standards.

To address miswire detection, the described system leverages the integrated circuit’s ability to monitor power at the LINE_HOT terminal during trip events. By detecting zero-cross signals at a designated pin, the integrated circuit determines whether the device is properly wired or in a miswire state. In miswired scenarios, the integrated circuit registers and maintains the miswire state in memory before losing power and prevents further operation of the device until proper wiring is restored. This approach eliminates the need additional detection circuits, reducing complexity and cost while enhancing safety. The miswire detection algorithm operates during each trip event, whether caused by first installation, manual testing, or actual fault conditions, ensuring reliable detection of wiring faults across all operational scenarios.

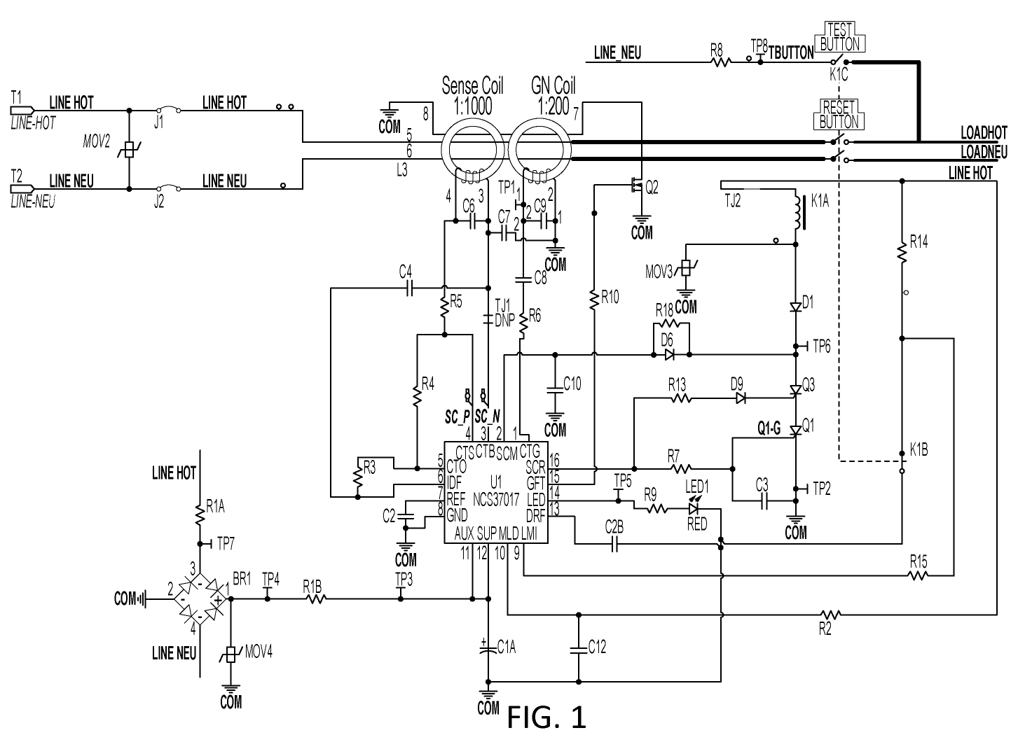

FIG. 1 shows an example circuit schematic of a GFCI electrical wiring device 100. The circuit schematic of FIG. 1 includes a sense coil 102 (i.e., a differential transformer), and a GN coil 102 (i.e., grounded neutral transformer). The operation of these coils will be understood by a person of ordinary skill in the art; briefly, however, a sense coil outputs a signal proportional to the vector difference of currents passing through the LINE_HOT and LINE_NEUTRAL conductors. This signal is received by controller U1, a NCS37017 chip, which, based on the signal, determines whether to trigger the circuit interrupter 104 according to an internal algorithm and in keeping with established industry standards for detecting the presence of a fault. Methods for detecting a fault based on the output of a differential transformer are well understood in the art and any suitable such method can be used. If a fault is detected—requiring that output of sense coil 102 exhibits a certain magnitude and persists for a predetermined period—controller U1 initiates a trip event, causing the circuit interrupter 104 to open. In the example of FIG. 1, initiating a trip comprises asserting SCR Q1 via SCR pin 16 to power solenoid K1A and trip the circuit interrupter 102. Circuit interrupters are likewise well known in the art and any suitable example can be used. An example of such an assembly is described in U.S. 11,990,301 herein incorporated by reference in its entirety.

A person of ordinary skill in the art will recognize that controller U1 is provided as an example of a controller, i.e., integrated circuit suitable to perform one or more of the functions described herein. In certain alternative examples, controller U1 can be configured to perform a simulated fault test in the manner described below (e.g., in accordance with method 200). In alternative examples, controller U1 can be configured to perform the miswire detection test as described below (e.g., in accordance with method 300). In certain examples, controller U1 can be configured to perform both the simulated fault test and the miswire detection test. In various examples, the controller may be implemented as a microcontroller, system-on-chip, or field-programmable gate array; however, a person of ordinary skill will understand that these are only provided as examples of suitable controllers. Furthermore, it will be understood that the implementation of a controller can include certain hardware (e.g., resistors, capacitors, amplifiers, etc.) that operates with controller to either configure controller or enable the operation of its functions.

In an example, controller U1 will periodically trigger a fault test to verify the ability of the electrical wiring device to properly detect a fault condition. For example, a grounded neutral fault condition occurs when the load neutral terminal, or a conductor connected to the load neutral terminal, becomes grounded. A person of ordinary skill in the art will recognize that a grounded neutral fault is only type of fault and that other types of fault conditions and methods of simulating them exist. The concept of performing a simulated fault test is well-understood in the art and required by UL standards.

As described above, previous designs for performing a fault test tended to rely on mechanisms for terminating the test before the actual trip threshold is reached. In other words, the test was performed for a length of time less than the actual length of time required for a trip under the standards. This was to ensure that the device could perform the test without causing the circuit interrupter to open. Opening each time a test was performed would render the device unusable, given the typical frequency of fault tests (e.g., every 3 seconds).

In the example of FIG. 1, controller U1 generates a simulated grounded neutral test signal by turning on FET Q2. When FET Q2 is turned ON, the GN Coil produces an oscillating signal that is a function of the full power supply voltage, by virtue of the grounded wire loop connected to Q2 and including a length (extending from 7 to 8) that passes through the toroids of the sense coil and the GN coil. The wire loop 402, in combination with the FET 404 (in the ON state), forms a loop that passes through the sense coil 102 and GN Coil 104 to simulate a grounded neutral condition. Thus, controller U1, via GFT pin 15, initiates the simulated grounded neutral test. This method of simulating a grounded neutral fault condition is described in US 10,020,649 incorporated herein by reference in its entirety. While the grounded wire loop is one method for simulating a grounded neutral fault other methods of simulating grounded neutral condition are known in the art and any suitable such method can be used.

Because controller U1 initiates the simulated grounded neutral test and is responsible for determining the presence of an actual ground fault, controller U1 can be configured to enter a test state when performing the simulated grounded neutral test in which a detected fault does not result in asserting SCR Q1 to trigger the circuit interrupter. Stated differently, controller U1 can permit the simulated grounded neutral test to persist for a period that would normally result in the trip, without asserting the SCR because it is expecting to detect a fault once the simulated grounded neutral test has been initiated. Controller U1 thus looks for the presence of a fault once the simulated grounded neutral test has begun but does not assert SCR Q1 to trip the circuit interrupter if the expected fault is detected within the expected window. If a predetermined period elapses without detecting the fault, controller U1 can cause the device to trip, and/or initiate some other indication that the device has failed the test (such as illuminating LED1). In certain examples, the test can be repeated with controller U1 configured to trigger the circuit interrupter or otherwise indicate a failed test if multiple self-tests are failed. As will be appreciated by a person of ordinary skill in the art, this method of desensitizing the controller can be applied for any type of simulated fault, not only grounded neutral faults.

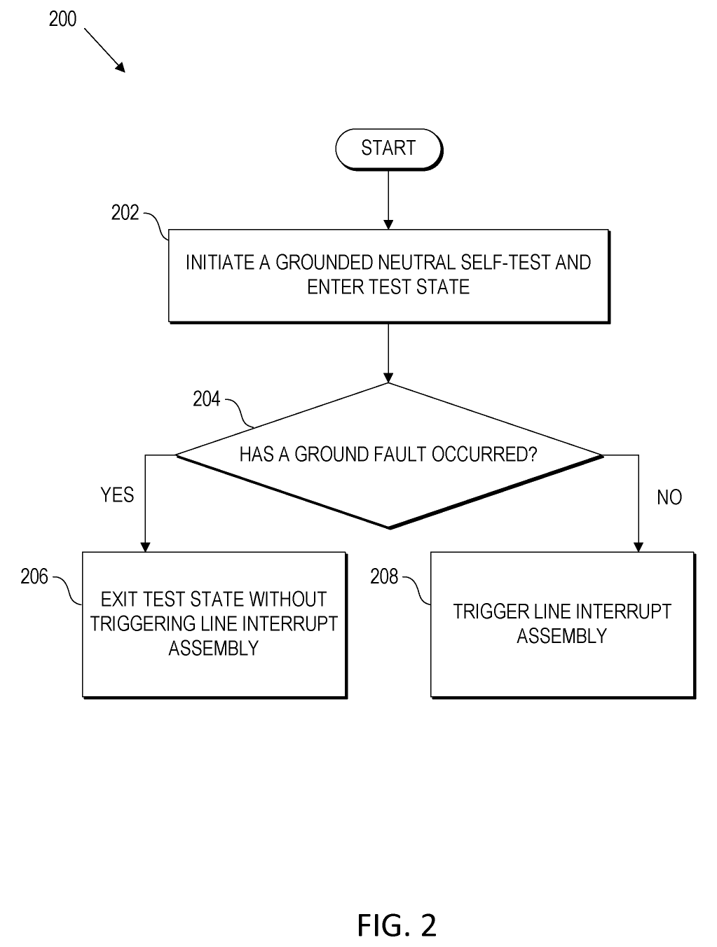

The algorithm for the fault test of controller U1 (of FIG. 1) is represented in the flowchart of FIG. 2 as method 200. It should be understood, however, that the method 200 of FIG. 2 can be implemented by any controller suitable for performing the steps described. The steps of method 200 can be stored in the non-transitory storage medium of the controller (e.g., controller U1) and executed or otherwise performed by controller during operation.

At step 202, a fault self-test is initiated, and a test state is entered. In the example of a grounded neutral fault self-test shown in FIG. 1, this is accomplished by asserting Q2 into conduction (via GFT pin 15), though other methods of initiating a fault self-test (including simulating other types of faults) can be used. It will be understood that the method of initiating a fault self-test will depend upon the structure and method employed for simulating the fault within the electrical wiring device.

At step 204, the output of sense coil 102 is monitored for a fault condition for a predetermined period of time. As described above, any suitable method for detecting a fault condition can be used by a controller. Fault detection is well understood, and its parameters are standardized within the art. Step 204 is represented as a decision block as it can result in alternative outcomes, steps 206 or 208, depending on whether a ground fault was detected within the predetermined period.

At step 206 upon determining that an actual fault condition was detected within the predetermined period of time, the test state is exited without triggering the circuit interrupter 106. Once the fault condition is detected, the fault self-test is concluded (i.e., the self-test has passed) and controller U1 can exit the test state such that any later-detected faults will result in controller U1 triggering the circuit interrupter 106.

At step 208, upon determining an actual fault condition was not detected after the predetermined period of time, the circuit interrupter 106 is triggered. A failure to detect an actual fault condition from the simulated fault within the predetermined period of time is an indication that the fault detection ability of the electrical wiring device has failed, and thus the device trips to signal to the user that the device must be replaced. If indeed the fault detection facility of the device has failed, resetting the device will result in repeated trips from subsequent self-tests (i.e., the method 200). In certain examples, another indication that the device has failed the test, such as illuminating LED1, can be performed to notify the user of the failure.

Previous designs, which used separate integrated circuits to (1) detect the presence of a fault and trigger the circuit interrupter and (2) to initiate the self test, typically could not permit the test to persist for a length of time that would normally represent a fault. The use of a single integrated circuit that detects the presence of a fault, triggers the circuit interrupter, and initiates the self-test, permits the self-test to occur for a length of time that would result in a fault by programming controller U1 to not assert the trigger the circuit interrupter during the simulated ground fault test window.

Controller U1 can further perform a miswire detection test. A miswire occurs when the LINE_HOT and LINE_NEUTRAL terminals are connected to the load while the mains line input is connected LOAD_HOT terminal and the mains neutral is connected to the LOAD_NEU terminal.

Controller U1 is powered via a connection to the LINE_HOT terminal (i.e., through bridge diode BR1). In a miswire state, where mains line input is connected to the LOAD_HOT and mains neutral is connected to the LOAD_NEU terminals, opening the circuit interrupter contacts (e.g., in response to an actual fault) will cause controller U1 to lose power, as LINE_HOT has been disconnected from the mains. Applicants have recognized that the loss of power in response to opening the line contacts presents an opportunity to detect the wiring state of the device.

In a miswire state, once the circuit interrupter contacts have been opened, controller U1 will remain operational for a brief period before losing power itself. (For example, capacitor C1A will not immediately discharge and provide sufficient power to controller U1 for operation for a brief period.) Thus, controller U1, before losing power, can check to determine whether LINE_HOT is connected to mains or is otherwise in a miswire state. If properly wired, controller U1 does not lose power because the connection to mains is not lost.

In this example of FIG. 1, controller U1 determines the presence of power at the LINE_HOT terminal by monitoring zero-crosses at MLD pin 10. MLD pin 10 is connected to LINE HOT via resistor R2. Detecting zero crosses (e.g., rising edge detection) is well known in the art and any suitable such method can be used.

Controller U1 can begin monitoring for the presence of power at the LINE_HOT terminal once a fault that would require a trip is detected. Alternatively, controller U1 can begin monitoring for the presence of power at the LINE_HOT terminal once it has triggered the circuit interrupter (e.g., by asserting SCR pin 16). In an alternative example, controller U1 can begin monitoring for the presence of power at LINE_HOT once it has determined that the interrupt assembly has successfully been tripped. For example, controller U1 can determine the state of the liner interrupt assembly by monitoring the state of switch K1B via LMI pin 9. K1B operates as the inverse of the state of line contacts. Thus, when the contacts of the circuit interrupter open, K1B closes. Conversely, when the contacts of the circuit interrupter close, K1B opens. When the device is in the reset state, K1B is open and the voltage at LMI pin 9 is proportional to LINE_HOT (via resistors R14 and R15). When the device is in the tripped state, K1B is closed, connecting the node between R14 and R15 to ground, and the voltage at LMI pin 9 is thus zero. The voltage LMI pin 9 is therefore a proxy for the trip status of the device. If another circuit is responsible for detecting triggering the trip event, detecting the trip event can comprise receiving the signal that triggers the circuit interrupter. It should be understood that these are provided merely as examples for detecting a trip event and any suitable method can be used. A trip event is usually marked by multiple components acting in concert, meaning that any number of signals between such components, including the components that detect and initiate the trip, can be monitored. Likewise, the trip event usually results in the loss of power to one or more components, which can likewise be monitored to detect the trip event.

Once the predetermined condition has occurred (e.g., detecting a fault state, triggering the circuit interrupter, or detecting circuit interrupter has triggered) controller U1 checks MLD pin 10 for the presence of zero crosses, which would indicate that LINE_HOT is properly connected to mains. If MLD pin 10 does not detect zero crosses after some predetermined period of time, it registers in memory a miswire state before it loses power, ensuring that a miswire state is maintained in memory when controller U1 loses power. This predetermined period of time can be less or significantly less than the time provided by energy stored in capacitor C1A. Upon reset and again receiving power, controller U1 will assert SCR 10 to trigger the circuit interrupter to prevent the operation of the device until the device has been rewired properly. (Controller U1 can, alternatively or additionally, provide other indications of a miswire state, such as illuminating LED1). Controller U1 can retain the miswire state in memory until the MLD pin 10 detects zero crosses on after a trip event, in which case a properly wired state is registered. A person of ordinary skill in the art will recognize that other suitable energy storage devices, such as a battery, can be used in place of capacitor C1A to supply power to controller U1 after a trip event so that the miswire test can occur.

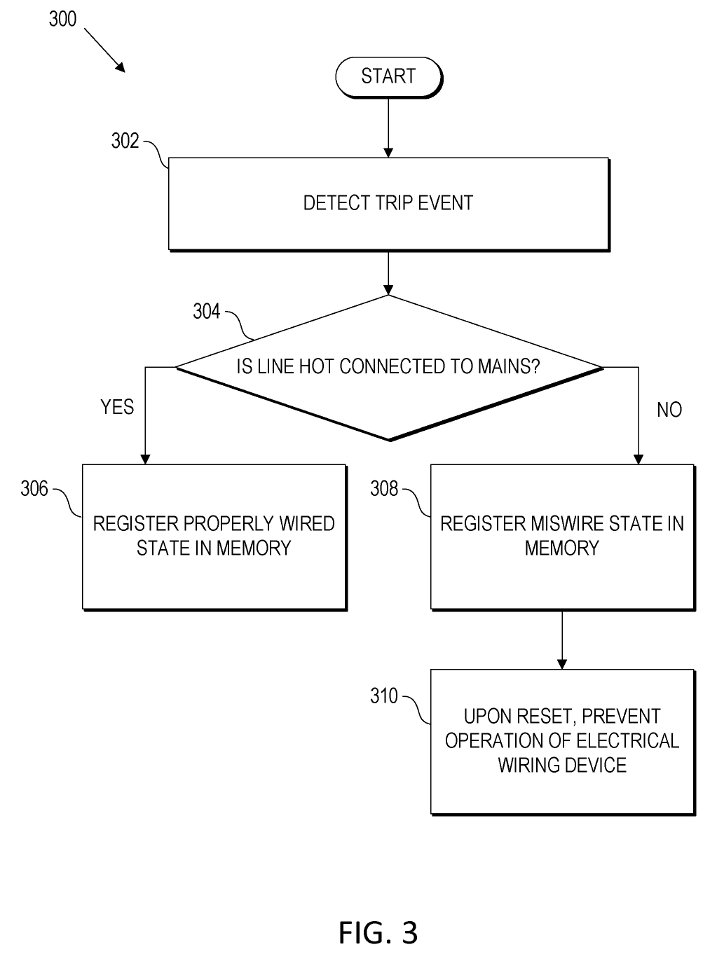

The algorithm for the miswire detection test of controller U1 (of FIG. 1) is represented in the flowchart of FIG. 3 as method 300. It should be understood, however, that method 300 of FIG. 3 can be implemented by any controller suitable for performing the steps described. The steps of method 300 can be stored in the non-transitory storage medium of the controller (e.g., controller U1) and executed or otherwise performed by controller during operation. Further, steps 304-308 occur after a trip event has occurred but before controller loses power.

At step 302, a trip event is detected. A trip event can be detected through any suitable method, including through monitoring a voltage signal that changes according to the state of the circuit interrupter, such as LMI pin 9 in the example of FIG. 1. Alternatively, if the controller triggers the circuit interrupter, the detection of the trip event can comprise triggering the circuit interrupter, or the detection of a ground fault interrupt which coincides with a trip event. Any other suitable method for detecting a trip event, which includes detecting signals that can operate as a proxy for a trip event, can be used.

At step 304, whether LINE HOT terminal is connected to mains. In an example, this can be determined by monitoring for presence of zero crosses in a signal indicative of the voltage of LINE HOT, e.g., MLD pin 10 in FIG. 1. It should be understood that other methods of reliably detecting whether the LINE HOT terminal is connected to mains can be used. For example, the peak voltage or average voltage of LINE HOT or a related signal can be detected once the circuit interrupter has tripped. If such voltage exceeds a threshold, it can be determined that LINE HOT is detected to mains. Step 304 is represented as a decision block as it can result in alternative outcomes, steps 306 or 308, depending on whether a ground fault was detected within the predetermined period.

At step 306, upon determining LINE_HOT is connected to mains, a properly wired state is registered in memory (or allowed to remain in memory if previously registered as properly wired). If the device is already registered as being properly wired, it does not need to write over this state. It can, instead, simply permit the existing registered state to persist.

At step 308, upon determining LINE_HOT is not connected to mains, a miswire state is registered in memory such that the miswire state is maintained in memory when power is lost at the controller.

At step 310, upon reset of the device, further operation of the device is permitted if a properly wired state is registered in memory. For example, if a miswire state has been maintained in memory, controller U1 can initiate a trip event to notify the user that the device is miswired. Additionally, an indicator such as LED1 can be illuminated to notify the user a miswire state has occurred.

Further, in order to check for the miswire state upon first install, controller U1 can be configured to trip the first time it is powered. It is worth noting that controller U1 only need to actively register a properly wired or miswire state in memory if the detected state is different from the state already registered.

The miswire algorithm will determine if the device is in a properly wired state upon each trip event, whether caused by first install, a manual test operation, or an actual fault condition (other than a self-test). Thus, the miswire algorithm presents a robust method of detecting a miswire state without requiring additional components.

It should be understood that the values used above are only representative values, and other values may be in keeping with the spirit and intention of this disclosure.

While several inventive embodiments have been described and illustrated herein with reference to certain exemplary embodiments, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein (and it will be understood by one skilled in the art that various changes in detail may be effected therein without departing from the spirit and scope of the invention as defined by claims that can be supported by the written description and drawings). More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto; inventive embodiments may be practiced otherwise than as specifically described and claimed. Further, where exemplary embodiments are described with reference to a certain number of elements it will be understood that the exemplary embodiments can be practiced utilizing either less than or more than the certain number of elements.

All references, including publications, patent applications, and patents, cited herein are hereby incorporated by reference to the same extent as if each reference were individually and specifically indicated to be incorporated by reference and were set forth in its entirety herein.

All definitions, as defined and used herein, should be understood to control over dictionary definitions, definitions in documents incorporated by reference, and/or ordinary meanings of the defined terms.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

The recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

1. An electrical wiring device for use within a residential or commercial electrical power system, the device comprising:
a line hot terminal,
a load hot terminal, wherein the line hot terminal and the load hot terminal are connected by a hot conductor;
a line neutral terminal,
a load neutral terminal, wherein the line neutral terminal and the load neutral terminal are connected by a neutral conductor;
a sense coil, the sense coil being configured to generate a signal proportional to a vector difference of currents present in the hot conductor and neutral conductor;
a circuit interrupter including separable contacts arranged between the line hot terminal and the load hot terminal; and
a controller configured to:
initiate a simulated fault self-test;
enter, during the simulated fault self-test, a non-trip test state in which detection of a fault condition based on an output of the sense coil does not cause actuation of the circuit interrupter; and
trigger the circuit interrupter upon failing to detect a fault condition within a predetermined period.

2. The electrical wiring device of claim 1, wherein the controller is further configured to exit the non-trip test state upon detecting a fault condition within the predetermined period.

3. The electrical wiring device of claim 1, further comprising: a conductor loop separate from the line hot terminal and the line neutral terminal and having a segment passing through the sense coil and the grounded neutral coil; a solid-state switch coupled to the conductor loop and operable to complete the conductor loop when activated by a controller, wherein initiating a simulated fault self-test comprises activating the solid-state switch.

4. The electrical wiring device of claim 1, wherein the device further comprises: an indicator coupled to the controller, the controller being further configured to cause the indicator to signal a failed simulated fault self-test upon failing to detect the fault condition within the predetermined period.

5. The electrical wiring device of claim 1, the controller being further configured to: detect a trip event of the circuit interrupter; and determine, before the controller loses power, whether the line hot terminal is connected to mains, wherein a a miswire state is maintained upon determining the line hot terminal is not connected to mains.

6. The electrical wiring device of claim 5, wherein determining whether the line hot terminal is connected to mains comprises detecting the presence of zero crosses at the line hot terminal.

7. The electrical wiring device of claim 6, wherein detecting the presence of zero crosses at the line hot terminal comprises detecting zero crosses at an input to the controller, the input to the controller being representative of the voltage at the line hot terminal.

8. The electrical wiring device of claim 5, further comprising: a capacitor electrically coupled to the controller, the capacitor being configured to supply power to the controller for a period after the circuit interrupter has tripped.

9. The electrical wiring device of claim 5, wherein the device further comprises: an auxiliary switch actuated in conjunction with the separable contacts, wherein detecting a trip event comprises detecting a signal conditioned by the state of the auxiliary switch.

10. The electrical wiring device of claim 5, wherein detecting a trip event comprises triggering the circuit interrupter by a signal output from the controller.

11. The electrical wiring device of claim 5, wherein the controller is further configured to disable further operation of the device upon subsequent power-up if a miswire state indicator is stored.

12. The electrical wiring device of claim 11, wherein disabling further operation of the device comprises triggering the circuit interrupter.

13. An electrical wiring device for use within a residential or commercial electrical power system, the device comprising:
a line hot terminal,
a load hot terminal, wherein the line hot terminal and the load hot terminal are connected by a hot conductor;
a line neutral terminal,
a load neutral terminal, wherein the line neutral terminal and the load neutral terminal are connected by a neutral conductor;
a sense coil, the sense coil being configured to generate a signal proportional to a vector difference of currents present in the hot conductor and neutral conductor;
a circuit interrupter including separable contacts arranged between the line hot terminal and the load hot terminal; and
a controller configured to:
detect a trip event of the circuit interrupter; and
determine, before the controller loses power, whether the line hot terminal is connected to mains, wherein a miswire state is maintained upon determining the line hot terminal is not connected to mains.

14. The electrical wiring device of claim 13, wherein determining whether the line hot terminal is connected to mains comprises detecting the presence of zero crosses at the line hot terminal.

15. The electrical wiring device of claim 14, wherein detecting the presence of zero crosses at the line hot terminal comprises detecting zero crosses at an input to the controller, the input to the controller being representative of the voltage at the line hot terminal.

16. The electrical wiring device of claim 13, wherein detecting a trip event comprises triggering the circuit interrupter by a signal output from the controller.

17. The electrical wiring device of claim 13, further comprising: a capacitor electrically coupled to the controller, the capacitor being configured to supply power to the controller for a period after the circuit interrupter has tripped.

18. The electrical wiring device of claim 13, wherein the device further comprises: an auxiliary switch actuated in conjunction with the separable contacts, wherein detecting a trip event comprises detecting a signal conditioned by the state of the auxiliary switch.

19. The electrical wiring device of claim 13, wherein the controller is further configured to disable further operation of the device upon subsequent power-up if a miswire state is stored.

20. The electrical wiring device of claim 17, wherein disabling further operation of the device comprises triggering the circuit interrupter.
